(19) United States
(12) Patent Application Publication
(10) Pub. No.: US 2025/0076342 A1
(43) Pub. Date: Mar. 6, 2025

(54) Apparatus, System and Method for Repairing a Test Contact Arrangement

(71) Applicant: PAC TECH - PACKAGING TECHNOLOGIES GMBH, Nauen (DE)

(72) Inventors: Thorsten Krause, Hoppegarten (DE); Christopher Schulz, Ketzin/Havel (DE); Andreas Meinecke, Berlin (DE)

(21) Appl. No.: 18/578,196

(22) PCT Filed: Mar. 16, 2023
(86) PCT No.: PCT/EP2023/056702

§ 371 Date: Jan. 10, 2024

(30) Foreign Application Priority Data
Mar. 30, 2022 (DE) 10 2022 107 543.5

(51) Int. Cl. G01R 3/00; G01R 1/073

(52) U.S. Cl. CPC G01R 3/00; G01R 1/07314

(57) ABSTRACT

An apparatus for repairing a test-contact arrangement includes: a movable arm at whose end effector at least one heat-conductive receptacle is formed, at which a heat-absorption surface is formed; a control device configured for controlling a movement of the arm; a heating device configured for heating the heat-absorption surface; and a temperature measuring device configured for measuring a radiation temperature of a solder material of the solder connection. The receptacle is configured for receiving at least one heat-conductive blade element, and the control device is configured for moving the blade element via a movement of the arm in relation to the test-contact arrangement to sever the at least one solder connection so that at least one solder bridge to be repaired is removable.

This application is the U.S. National Stage of International Appln No. PCT/EP2023/056702, filed 16 Mar. 2023, which claims the benefit of German Application No. 10 2022 107 543.5 filed Mar. 30, 2022. Each of the above-referenced applications is incorporated herein by reference in its entirety.

The disclosure at hand relates to an apparatus for repairing a test-contact arrangement comprising a test-contact carrier and a plurality of test contacts which are each spaced apart from each other on at least one contact surface of the test-contact carrier and of which at least two are connected via at least one solder connection via a solder bridge to be repaired. The device comprises a movable arm or movement arm at whose end effector at least one heat-conductive receptacle is formed. A heat-absorption surface is formed at the receptacle. Furthermore, the device comprises a control device configured for controlling a movement of the arm, a heating device configured for heating the heat-absorption surface, and a temperature measuring device configured for measuring a radiation temperature of a solder material of the solder connection. Furthermore, the disclosure at hand relates to a system having at least one test arrangement and an embodiment of the apparatus and to a method for repairing a test-contact arrangement.

Methods and devices for producing a test-contact arrangement are known in different embodiments. WO 2017/026802 A1 discloses a method and a device, the individual test contacts being gripped by a gripping tool for contacting the test contacts on a test-contact carrier and with their lower edge being immersed in a solder material bath for wetting said lower edge intended for being contacted with a contact surface of the contact carrier. Subsequently, the lower edge of the test contact is positioned on a contact surface of the test-contact carrier by means of the gripping tool and the solder material is subjected to laser radiation for producing a solder-material connection between the test contact and the test-contact carrier.

Furthermore, methods and devices for repairing a test-contact arrangement are generally known. For instance, DE 10 2018 119 137 A1 discloses a method and a device for repairing a test-contact arrangement in both of which an at least uniaxial movement of a gripping tool is controlled to correct a faulty position of a test contact of the test-contact arrangement by means of the movement. In doing so, the test contact is repositioned to a target position to repair the test-contact arrangement.

Furthermore, methods and devices are known via which a solder bridge provided at a test-contact arrangement can be repaired. Hitherto, the repair of a solder bridge on a test-contact arrangement or on a printed circuit board has only been possible, however, by removing or detaching the test contacts, also referred to as pins, along with the solder material. This makes repairing solder bridges in the state of the art complicated, as several steps are required to restore the function of the test-contact arrangement. Thus, new test contacts must be disposed on the test-contact arrangement after the removal of the solder bridge. Due to the narrow spacing between the individual test contacts on the test-contact carrier, this new positioning is work-intensive and bears the risk of a faulty arrangement, which would also have to be repaired via a reparative measure. As a consequence, deviations can arise between the test contacts, meaning a pitch, i.e., the spacing between two adjacent test contacts in a row of the corresponding test-contact arrangement in each instance, is no longer correct. An incorrect pitch results in a faulty function of the test contact arrangement.

Therefore, the object of the disclosure at hand is to propose an apparatus and/or a method via which the disadvantages of the state of the art, which arise when removing solder bridges, can be overcome. In particular, it is an object to enable the removal of solder bridges during the process of repairing solder joints, thus avoiding damage to the test contacts, without a debonding of test contacts being necessary.

To attain this object, an apparatus having the features of independent claim 1 is proposed. Further, a system having an apparatus of this kind is proposed. Equally, a method having the features of independent claim 10 is proposed.

Advantageous embodiments of the disclosure are the subject matter of the dependent claims. All combinations of at least two features disclosed in the description, the claims and/or the figures are part of the scope of the disclosure. It goes without saying that the explanations regarding the device equally pertain to the system according to the disclosure, without having to be mentioned separately. All features and embodiments disclosed regarding the device pertain equally, if not a verbatim manner to the method according to the disclosure. In particular, linguistically common rephrasing and/or an analogous replacement of respective terms within the scope of common linguistic practice, in particular the use of synonyms backed by the generally recognized linguistic literature, are of course comprised by the content of the disclosure at hand without every variation having to be expressly mentioned.

In a first aspect, the disclosure relates to an apparatus for repairing a test-contact arrangement comprising a test-contact carrier and a plurality of test contacts which are each spaced apart from each other on at least one contact surface of the test-contact carrier and of which at least two are connected via at least one solder connection via a solder bridge to be repaired. The apparatus comprises a movable arm or a movement arm, which is preferably also referred to as a cantilever, at whose end effector at least one heat-conductive receptacle is formed. A heat-absorption surface is formed at the receptacle. Furthermore, the apparatus comprises a control device configured for controlling a movement of the arm, a heating device configured for heating the absorption surface, and a temperature measuring device configured for measuring a radiation temperature of a solder material of the solder connection. The apparatus is characterized in that the receptacle is configured for receiving at least one heat-conductive blade element, and the control device is configured for moving the blade element via a movement of the arm in relation to the test-contact arrangement in order to sever the at least one solder connection so that the at least one solder bridge to be repaired is removable.

In a second aspect, the disclosure relates to a method for repairing a test-contact arrangement which comprises a test-contact carrier and a plurality of test contacts which are each spaced apart from each other on at least one contact surface of the test-contact carrier and of which at least two are connected via at least one solder connection via a solder bridge to be repaired, the method comprising the following steps: heating a receptacle of an end effector via a heat-absorption surface formed thereon; moving the end effector in relation to the test-contact arrangement; and measuring a radiation temperature of a solder material of the solder connection. The method according to the disclosure is characterized in that the receptacle has at least one heat-conductive blade element and the movement of the end effector in relation to the test-contact arrangement is controlled in such a manner that the at least one solder connection is severed, in particular using a cutting movement, by the blade element in order to remove the at least one solder bridge to be repaired.

In a third aspect, the disclosure relates to a repair system, comprising at least one test-contact arrangement which comprises a test-contact carrier and a plurality of test contacts which are each spaced apart from each other on at least one contact surface of the test-contact carrier and of which at least two are connected via at least one solder connection via a solder bridge to be repaired, and comprising an apparatus according to any embodiment of the disclosure.

Particularly preferably, the disclosure relates to a repair system comprising an apparatus according to any embodiment of the disclosure and a plurality of in particular different blade elements, which can be disposed at the receptacle so as to be exchangeable.

Consequently, a set of preferably different blade elements is provided, from which a suitable blade element can be chosen as the situation demands, in particular depending on a solder bridge to be repaired. The plurality of blade elements can preferably be provided in a stand in such a manner that a predetermined blade element can be disposed at the receptacle via a movement of the arm to the stand.

The removal and/or detachment of a solder bridge during a repair process of a test-contact arrangement, in particular a fine pitch probe card, has hitherto only been possible by the test contacts also being detached. This was disadvantageous, as the test contacts were no longer available as connective positions after the removal of the corresponding solder bridge. In order to fully restore the functionality of the test-contact arrangement, it has been necessary to dispose anew the test contacts removed with the solder bridge on the test-contact carrier. The apparatus according to the disclosure and the method according to the disclosure now make it possible to remove a solder bridge from a test-contact arrangement, without a test contact having to be detached in doing so. The method according to the disclosure is thus distinctly easier in its handling and in particular makes it possible to forgo further reparative measures, which have been necessary in the state of the art after the detachment of a solder bridge. According to the disclosure, the advantages are attained in particular by the at least one solder bridge being severed, in particular cut, by the blade element. For this purpose, the blade element has at least one “sharp” blade, via which the solder connection can be severed. In the state of the art, a “scraping off” of the solder connection has hitherto been necessary, during which process the corresponding test contact was also removed. In particular, a use of the device in a LaPlace-Can repair process seems advantageous, which is offered for the repair of fine pitch probe cards by the applicant and in which a solder connection of a test contact for correcting a faulty position of the test contact by means of an at least partially heatable gripping tool is fused, meaning the test contact can be gripped and repositioned. Via the solution according to the disclosure, which does not require a detachment of a test contact, the extent of the reparative function is enhanced with respect to the disclosure.

In this application, the phrase “at least one” is understood to mean the apparatus and/or the method according to the disclosure can comprise one or more of the corresponding components. The test-contact arrangement is preferably a test-contact arrangement having a slight pitch, i.e., a narrow spacing, of in particular <0.5 mm between the individual test contacts disposed in a grid and on the test-contact carrier. The pitch preferably describes a center-to-center spacing between two test points or component links, in particular between the test contacts of the test-contact arrangement. Test-contact arrangements of this kind are also referred to as fine pitch probe cards. A test contact preferably describes a pin, i.e., a test point and/or a link contact of the test-contact arrangement. A solder bridge is preferably a connective element made of conductive and solderable material for producing a conductive connection between two or more test contacts on the test-contact arrangement. Moreover, a solder bridge can also be an unintended electric and mechanical connection, in particular to be repaired in the sense of the disclosure, between two or more electric test contacts. If a solder bridge is faulty or has faulty locations because of degeneration, the electric connection is interrupted, meaning measuring faults can be caused, for example. The solder connection can preferably be a mechanical and electrical connection provided between at least one test contact and a solder bridge or a test-contact carrier for connection of the same. Lead, tin, zinc, silver and/or copper can be used as the solder material, for example. In this application and in general in robot technology, the last element of a kinematic chain-the kinematic chain of the arm in this instance-is referred to as “end effector”. In this application, the end effector is preferably designed as the receptacle, in particular a tool receptacle, or has the receptacle. The heat-absorption surface formed at the receptacle preferably describes a part of the receptacle designed to be heated via a heat current or energy input. The heat-absorption surface can be a flank of the receptacle, for example. The control device preferably has at least one processor and/or a volatile and/or non-volatile memory and can be configured as a system-on-a-chip or as a printed-circuit-board control or the like. The temperature measuring device is preferably configured for a contactless measuring of the radiation temperature of the solder material. The temperature measuring device preferably has an infrared-measuring unit. The radiation temperature, in particular also referred to as radiation equivalent temperature, preferably describes the thermal radiation of the surface of the solder connection and the specific emissive power of the surface material, in this case the solder material. The blade element is preferably disposed at the receptacle in such a manner that it is in heat-conducting contact, meaning a heat introduced in the receptacle via the heat-absorption surface may be transferred to the blade element. The heat-conductive connection is preferably established by the blade element being in direct contact with the receptacle and preferably being in contact with at least sections thereof.

According to a preferred embodiment, the control device is configured for moving the arm in such a manner that the at least one blade element carries out a cutting movement via which the at least one solder connection is severable. Particularly preferably, a movement of the blade element is optimized in a vertical direction (z direction) to enable an optimal separating effect. A speed of the cutting movement is preferably limited to 1.0 mm/second, preferably 0.75 mm/second, particularly preferably 0.5 mm/second. At this cutting speed, the blade element can optimally immerge into the solder to be severed in order to sever it.

The speed of the shearing force for tearing or severing the solder after a completed movement in the z direction is limited to 1 mm/second for effectively exploiting the force-shearing effect and for simultaneously avoiding a tilting of the blade element. Particularly preferably, according to the disclosure, a process-controlled drive program for moving the arm via the control device is activated and executed, the at least one blade element, which is disposed at the receptacle, being moved in relation to the test-contact arrangement in such a manner that the at least one solder bridge can be detached, in particular with the aid of thermal energy. The test-contact arrangement is preferably unmoved during the repair and is received so as to be immovable in a tool receptacle.

Particularly preferably, a predetermined cutting position, where the solder bridge is to be detached via the blade element, is registered via image evaluation by means of an optical device, in particular a camera. Based on the image data, a template can then preferably be determined for carrying out the cutting movement and a solder bridge can be severed by guiding the blade along the template. In other words, the arm is moved in relation to the test-contact arrangement, in particular along a template, based on the image data so that the cutting movement can be carried out. Particularly preferably, the apparatus has two optical devices, which are spaced apart, and/or a stereo camera for this purpose so that a depth evaluation of image data, in particular by means of trigonometry, is also possible. Particularly preferably, the apparatus therefore has at least one optical device configured for optically capturing the test-contact arrangement in the form of image data, for identifying from the captured image data a severing position to be met where the solder bridge is to be severed via the at least one blade element, and for transmitting the identified severing position to be met to the control device in the form of control signals, based on which the control device controls the movement of the arm to the severing position to be met. Particularly preferably, the control device is configured for controlling the arm at the severing position in such a manner that the arm carries out the cutting movement for severing the solder bridge.

According to a preferred embodiment, the blade element has a heat-conductive connection to the heat-absorption surface and is configured for heating the at least one solder connection to a softening temperature of the solder material. In other words, the blade element has a heat-conductive connection to the heat-absorption surface and is thus heated in such a manner that the at least one solder connection is heated to at least a softening temperature of the solder material. The blade element is preferably disposed at the receptacle or received thereby so that at least areas or sections of the blade element are in contact with the receptacle in a heat-conducting connection. Particularly preferably, a thermal conductivity coefficient of the blade element is at least of the same magnitude as a thermal conductivity coefficient of the receptacle. The blade element is preferably produced of a material containing tungsten carbides. Particularly preferably, the blade element is produced of a silicon-infiltrated tungsten carbide and/or a cobalt-infiltrated tungsten carbide. The blade element preferably has a thickness between 20 μm and 100 μm, preferably a thickness of 30 μm or 40 μm or 50 μm. Naturally, the blade element can also have any other thicknesses not explicitly mentioned.

Alternatively, it is possible for the blade to be provided with a DLC coating (diamond-like-coating coating) to improve the hardness and the surface roughness. Particularly preferably, the blade element has at least one abutment surface, with which it is in direct contact with a corresponding counter contact surface of the receptacle.

According to a preferred embodiment, the heating device comprises a laser unit configured for heating the heat-absorption surface via a laser beam to be directed thereon. In other words, the heat-absorption surface is irradiated with a laser beam in order to heat the receptacle and thus the blade element. Particularly preferably, the receptacle and thus the blade element are heated via a laser. This in particular allows contactless heating. Preferably, irradiation of the heat-absorption surface takes place with a wavelength in the range of blue light to infrared radiation, namely in the range of a wavelength of 380 nm to 1 mm. Particularly preferably, irradiation takes place in a range from 380 nm to 500 nm or in a range from 780 to 1 mm. In particular, wavelengths ranging from 380 nm to 500 nm enable a longer service life of the blade element owing to an improved absorption into a metal material. Preferably, the improved absorption effect results in a slighter thermal reciprocal effect in the material. In particular, wavelengths ranging from 780 nm to 1200 nm have an economical advantage, as an inexpensive integration is possible, and alternatively or additionally the possibility of providing an active temperature control exists.

Further preferably, a rectangular surface of the heat-absorption surface is subjected to laser radiation. This can be executed preferably by bundling the laser radiation by means of a mask and/or orientation optics, in particular by means of a collimator. The laser unit is preferably configured for focusing at least the heat-absorption surface of the receptacle even when the receptacle is moving to thus allow an uninterrupted heat input into the receptacle. A focus of this kind of the heat-absorption surface can, for example, take place via optically tracking the heat-absorption surface, e.g., by means of at least one camera.

According to a preferred embodiment, the heating device is configured for heating the heat-absorption surface via a hot nitrogen fluid flow. In other words, a hot nitrogen fluid flow flows against the heat-absorption surface to heat the receptacle and thus also the blade element. Generally, the heat-absorption surface can also be heated using a different fluid flow. However, a nitrogen fluid flow is preferred owing to the low reactivity of nitrogen and its ready availability. Particularly preferably, the heating device is configured for focusing at least the heat-absorption surface of the receptacle even when the receptacle is moving to thus allow an uninterrupted heat input into the receptacle.

According to a preferred embodiment, the temperature measuring device comprises a temperature-control unit configured for regulating a thermal performance of the heating device as a function of the radiation temperature of the solder material. In other words, a thermal performance for heating the receptacle is regulated as a function of the measured radiation temperature of the solder material. Particularly preferably, the device has a TC circuit. The temperature control (TC) circuit is preferably closed. If the temperature measuring device registers, for example, that the radiation temperature of the solder temperature does not correspond to a predetermined target temperature and/or to a predetermined target temperature interval, i.e., it is not met or is exceeded, for example, the heat or energy input into the receptacle is correspondingly adapted. For instance, an intensity of the laser beam or of the nitrogen fluid flow is increased or reduced for this purpose. Particularly preferably, the heating device communicates with the control device for this purpose. Particularly preferably, the temperature control unit is comprised in the control device, meaning only one control is required.

According to a preferred embodiment, the receptacle has a gripper or a vacuum suction unit configured for receiving the at least one blade element. In other words, the at least one blade element is received by a gripper or vacuum suction unit provided at the receptacle before commencing the repair process and is disposed at the receptacle. For instance, the at least one blade element can be clamped between two grippers in order to be disposed at the receptacle. Alternatively, the receptacle can have a vacuum suction unit, via which the at least one blade element can be received, in particular suctioned. Via the gripper and/or the vacuum suction unit, the blade element can be disposed at the receptacle in a preferably reversible or detachable manner. This makes it possible to exchange a blade element for another blade element which is possibly more favorable for a certain application case depending on the situation. The at least one blade element can, for example, be chosen from a set of blade elements as a function of a solder bridge to be removed and can be disposed at the receptacle.

According to a preferred embodiment, the blade element has a Scandi grind, in particular having a secondary bevel, at least on one side and/or a flat grind, in particular having a secondary bevel, and/or a sabre grind and/or a hollow grind and/or a convex grind and/or a one-sided flat grind and/or an at least one-sided convex grind and/or a beveled grind and/or a sabre grind and/or a saw-tooth grind and/or a serrated grind and/or a crinkle cutting grind. The grinds mentioned above are merely exemplary and are not to be understood as limiting the scope of the disclosure. In particular, the at least one blade element can also have several blade sections and/or blade tips. Equally, several blade elements can be disposed at the receptacle, e.g., at a predetermined spacing to each other, in order to sever, in particular detach, two or more solder connections at the same time, for example. Via the at least one blade element, the solder connection is preferably not only severed but the solder material is additionally fused via the heated blade element to yield the severing. Preferably, the severing is executed when the solder material is at least partially fused, in particular before the solder material is completely fused. Thus, the solder material can be severed easily and efficiently.

In this context, a Scandi grind has proven the best for the double-sided severing of the solder bridge, as its wedge shape at the tip yields a quick and optimal severing. The generated gap or the cutting kerf is preferred particularly for greater spacing and/or large amounts of solder material to be severed, as otherwise an action of force on the test contacts (also referred to as test pins) might be exerted via a solder movement. In this case, a lateral shearing movement can be used when carrying out the severing, for example. A one-sided flat grind allows a deep immersion into the solder bridge and produces a sharp (cut or severed) edge without exerting much force. Thus, preferably a small gap is yielded which preferably does not bear a risk of a force exertion, which is caused in particular by displaced solder material, to an adjacent test pin. This is preferred in particular when the test contacts are in close proximity to each other, i.e., are spaced closely together, meaning there is a risk of displacement due to an accumulation of solder material. The hollow grind is preferred for a close-meshed arrangement of the test contacts and/or for low solder-bridge heights, as only little solder material need be displaced. The serrated grind is preferably used when larger amounts of solder material are to be severed, which are severed in particular slowly by means of a feed motion. The saw-tooth grind is preferably used for larger amounts of oxidized solder material which are severed slowly by means of a traction movement.

Of course, the embodiments and the exemplary embodiments mentioned above and yet to be discussed below can be realized not only individually but also in any combination with each other, without departing from the scope of the present disclosure. Moreover, the embodiments and exemplary embodiments mentioned above and yet to be discussed below also relate to the method according to the disclosure in an equivalent or at least similar manner, without having to be mentioned separately.

Embodiments of the disclosure are shown schematically in the drawings and are described in the following in an exemplary manner.

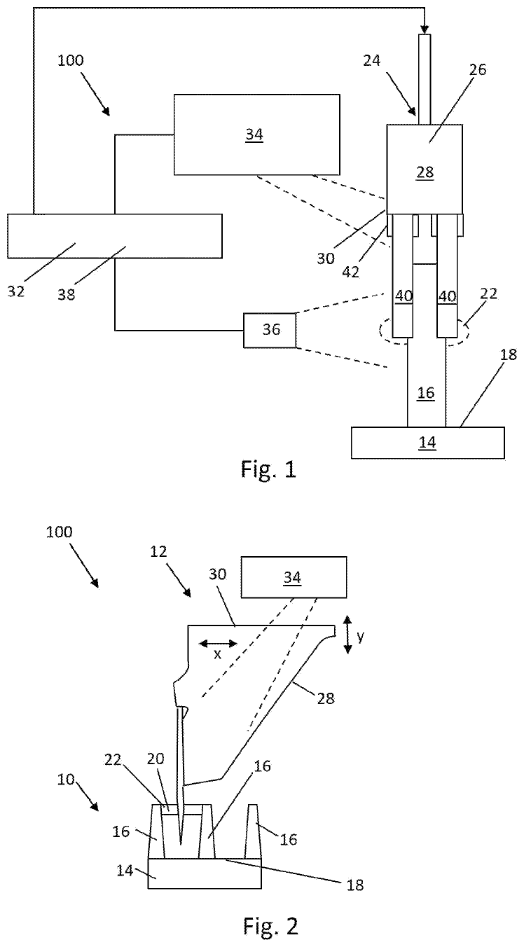

FIG. 1 shows a schematic exemplary embodiment of an apparatus according to the disclosure:

FIG. 2 shows a detailed view of an exemplary embodiment of an apparatus according to the disclosure:

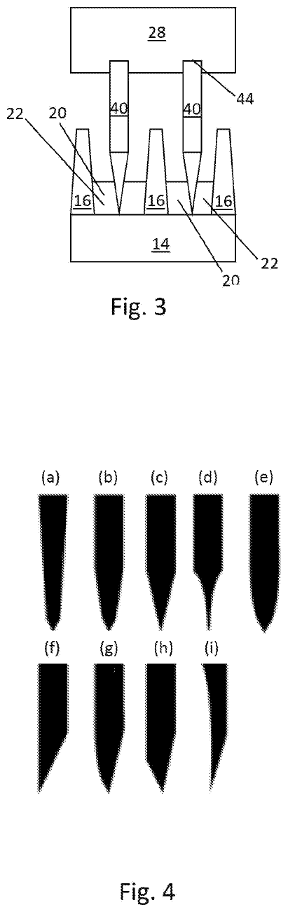

FIG. 3 shows a schematic detailed view of a blade element at a test-contact arrangement:

FIG. 4 shows a first schematic, exemplary view of different blade elements; and

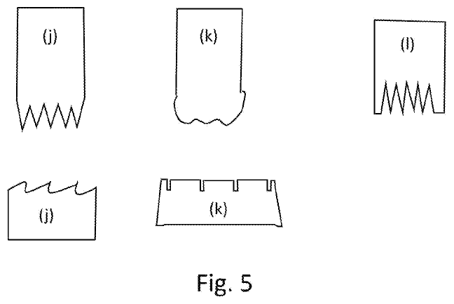

FIG. 5 shows a second schematic, exemplary view of different blade elements.

FIG. 1 shows a repair system 100, comprising a test-contact arrangement 10 and an apparatus 12 for repairing test-contact arrangement 10. Test-contact arrangement 10 comprises a test-contact carrier 14 and a plurality of test contacts 16 (see also FIG. 2). The plurality of test contacts 16 are spaced apart from each other on a contact surface 18 of test-contact carrier 14. The spacing between test contacts 16 is referred to as pitch. Exemplarily, two of the plurality of test contacts 16 are connected via at least one solder connection 22 via a solder bridge 20 to be repaired (also see FIG. 3).

Apparatus 12 comprises a movable arm 24 at whose end effector 26 at least one heat-conductive receptacle 28, in particular a tool receptacle, is formed. A heat-absorption surface 30 is formed at receptacle 28. Apparatus 12 further comprises a control device 32 configured for controlling a movement of arm 24 in particular in a three-dimensional space. According to FIG. 2, two spatial dimensions x, y, in which arm 24 is movable, are illustrated exemplarily. Additionally, arm 24 is also movable along a z direction (pointing inward to the sheet plane in FIG. 2). Furthermore, apparatus 12 has a heating device 34 configured for heating heat-absorption surface 30 preferably without contact. Heating device 34 is, for example, a laser unit and/or a laser module or a heating device which focuses a hot nitrogen fluid flow on heat-absorption surface 30. Likewise, apparatus 12 has a temperature measuring device 36 configured for measuring a radiation temperature of a solder material of solder connection 22. Exemplarily, according to FIG. 1, apparatus 12 comprises a temperature-control device 38 configured for controlling a thermal performance of heating device 34 as a function of the measured radiation temperature of the solder material. Thus, a feedback from a control point of view exists between temperature measuring device 36 and control device 32. For this purpose, control device 32 is designed as temperature control device 38.

Apparatus 12 is characterized in that receptacle 28 is configured for receiving at least one heat-conductive blade element 40. Control device 32 is configured for moving blade element 40 in relation to test-contact arrangement 10 via a movement of arm 24, to sever the at least one solder connection 22 so that the at least one solder bridge 20 to be repaired is removable. For this purpose, arm 24, in particular receptacle 28 where the at least one blade element 40 is disposed, is displaced at least along the x and/or y and/or z direction. A control of a rotatory movement around at least one of the main movement axes x, y, z is also possible. According to FIG. 1, receptacle 28 comprises two blade elements 40, which are disposed at receptacle 28 in such a manner that they move past both sides of test contact 16 (viewed along its longitudinal extension) synchronically to sever solder connection 22.

Control device 32 is configured for moving arm 24 in such a manner that the at least one blade element 40 executes a cutting movement via which the at least one solder connection 22 is severable. Furthermore, blade element 40 is in heat-conductive contact with heat-absorption surface 30 and is configured for heating the at least one solder connection 22 to a softening temperature of the solder material. This softening temperature preferably depends on the material and describes a threshold temperature, at which the solder material departs the solid state and changes to a deformable or liquid state.

Blade element 40 can be held at receptacle 28 via a gripper 42 (see FIG. 1) or via a vacuum suction unit 44 (see FIG. 3), for example.

In FIG. 4 and FIG. 5, different blade shapes of the at least one blade element 40 are shown exemplarily, which are each preferably used depending on the solder bridge to be severed. The different blade forms are marked with different letters (a) to (1) in the present illustration.

The following can be seen: (a) blade element 40 having a Scandi grind having a secondary bevel; (b) blade element 40 having a flat grind having a secondary bevel; (c) blade element 40 having a sabre grind; (d) blade element 40 having a hollow grind; (e) blade element 40 having a convex grind; (f) blade element 40 having a one-sided flat grind; (g) blade element 40 having at least one one-sided convex grind; (h) blade element 40 having a beveled grind and a sabre grind; (i) blade element 40 having a beveled grind and a hollow grind; (j) blade element 40 having a saw-tooth grind; (k) blade element 40 having a serrated grind; and (1) blade element 40 having a crinkle cutting grind. FIGS. 5 (j) and 5 (k) show blade element 40 in two views each

1. An apparatus for repairing a test-contact arrangement comprising a test-contact carrier and a plurality of test contacts which are each spaced apart from each other on at least one contact surface of the test-contact carrier and of which at least two are connected via at least one solder connection via a solder bridge to be repaired, the apparatus comprising the following:
a movable arm at whose end effector at least one heat-conductive receptacle is formed, at which a heat-absorption surface is formed;
a control device configured for controlling a movement of the arm;
a heating device configured for heating the heat-absorption surface; and
a temperature measuring device configured for measuring a radiation temperature of a solder material of the solder connection, wherein
the receptacle is configured for receiving at least one heat-conductive blade element, and the control device is configured for moving the blade element via a movement of the arm in relation to the test-contact arrangement in order to sever the at least one solder connection so the at least one solder bridge to be repaired is removable.

2. The apparatus according to claim 1,
wherein
the control device is configured for moving the arm in such a manner that the at least one blade element carries out a cutting movement via which the at least one solder connection is severable.

3. The apparatus according to claim 1, wherein the blade element has a heat-conductive connection to the heat-absorption surface and is configured for heating the at least one solder connection to a softening temperature of the solder material.

4. The apparatus according to claim 1, wherein the heating device comprises a laser unit configured for heating the heat-absorption surface via a laser beam to be directed thereon.

5. The apparatus according to claim 1, wherein the heating device is configured for heating the heat-absorption surface via a hot nitrogen fluid flow.

6. The apparatus according to claim 1, wherein the temperature measuring device comprises a temperature-control unit configured for regulating a thermal performance of the heating device as a function of the radiation temperature of the solder material.

7. The apparatus according to claim 1, wherein the receptacle has a gripper or a vacuum suction unit configured for receiving the at least one blade element.

8. The apparatus according to claim 1, wherein the blade element has a Scandi grind having a secondary bevel at least on one side and/or a flat grind having a secondary bevel and/or a sabre grind and/or a hollow grind and/or a convex grind and/or a one-sided flat grind and/or an at least one-sided convex grind and/or a beveled grind and/or a sabre grind and/or a saw-tooth grind and/or a serrated grind and/or a crinkle cutting grind.

9. A repair system, comprising at least one test-contact arrangement which comprises a test-contact carrier and a plurality of test contacts which are each spaced apart from each other on at least one contact surface of the test-contact carrier and of which at least two are connected via at least one solder connection via a solder bridge to be repaired and comprising apparatus according to claim 1.

10. A method for repairing a test-contact arrangement which comprises a test-contact carrier and a plurality of test contacts which are each spaced apart from each other on at least one contact surface of the test-contact carrier and of which at least two are connected via at least one solder connection via a solder bridge to be repaired, the method comprising the following steps:
heating a receptacle of an end effector via a heat-absorption surface formed thereon;
moving the end effector in relation to the test-contact arrangement; and
measuring a radiation temperature of a solder material of the solder connection,
wherein
the receptacle has at least one heat-conductive blade element and the movement of the end effector in relation to the test-contact arrangement is controlled in such a manner that the at least one solder connection is severed by the blade element in order to remove the at least one solder bridge to be repaired.

11. The method according to claim 10,
wherein
the blade element has a heat-conductive connection to the heat-absorption surface and is thus heated in such a manner that the at least one solder connection is heated to a softening temperature of the solder material.

12. The method according to claim 10,
wherein the heat-absorption surface is irradiated with a laser beam or a nitrogen fluid flow flows against the heat-absorption surface in order to heat the receptacle and the blade element.

13. The method according to claim 10, wherein a thermal performance for heating the receptacle is regulated as a function of the measured radiation temperature of the solder material.

14. The method according to claim 10, wherein the at least one blade element is received by a gripper or vacuum suction unit provided at the receptacle before commencing the repair process and is disposed at the receptacle.

15. The method according to claim 10, wherein the at least one solder connection is severed by the at least one blade element having a Scandi grind having a secondary bevel at least on one side and/or a flat grind having a secondary bevel and/or a sabre grind and/or a hollow grind and/or a convex grind and/or a one-sided flat grind and/or an at least one-sided convex grind and/or a beveled grind and/or a sabre grind and/or a saw-tooth grind and/or a serrated grind and/or a crinkle cutting grind.
